(19) United States
(12) Patent Application Publication
(10) Pub. No.: US 2024/0310490 A1
(43) Pub. Date: Sep. 19, 2024

(54) SENSOR ELEMENT AND RANGING SYSTEM

(71) Applicant: SONY SEMICONDUCTOR SOLUTIONS CORPORATION, KANAGAWA (JP)

(72) Inventors: MUTSUMI OKAZAKI, KANAGAWA (JP); SHOHEI SHIMADA, KANAGAWA (JP)

(21) Appl. No.: 18/550,294

(22) PCT Filed: Jan. 20, 2022
(86) PCT No.: PCT/JP2022/001897

§ 371 Date: Sep. 13, 2023

(30) Foreign Application Priority Data
Mar. 24, 2021 (JP) 2021-049543

(51) Int. Cl. G01S 7/481; G01S 17/08

(52) U.S. Cl. CPC G01S 7/4816; G01S 17/08

(57) ABSTRACT

The present disclosure relates to a sensor element and a ranging system that can achieve further downsizing and high functionality. A sensor element includes: a sensor substrate in which a SPAD is provided on a semiconductor substrate for each pixel; a logic substrate laminated on the sensor substrate and provided with a logic circuit; and a plurality of transistors used to output a signal according to a cathode voltage or an anode voltage of the SPAD. Then, at least some of the plurality of transistors are provided in a well formed in the semiconductor substrate of the sensor substrate. The present technology can be applied to, for example, a ranging system that performs ranging using a ToF method.

### TECHNICAL FIELD

The present disclosure relates to a sensor element and a ranging system, and more particularly to a sensor element and a ranging system that can be further downsized and have higher functionality.

### BACKGROUND ART

In recent years, a distance image sensor that measures a distance by a time-of-flight (ToF) method has attracted attention. In the distance image sensor, for example, a pixel array in which pixels using a single photon avalanche diode (SPAD) are arranged in a matrix is adopted. In the SPAD, avalanche amplification occurs when one photon enters a PN junction region of a high electric field in a state where a voltage larger than a breakdown voltage is applied. By detecting a timing at which a current instantaneously flows at that time, a distance can be measured with high accuracy.

For example, Patent Document 1 discloses a photodetector including a high electric field region, a separation region for separation from an adjacent pixel, and a hole accumulation region that traps electrons on a side wall of the separation region, in which the hole accumulation region is electrically connected to an anode.

### CITATION LIST

### Patent Document

Patent Document 1: WO 2020/074530 A

### SUMMARY OF THE INVENTION

### Problems to be Solved by the Invention

By the way, conventionally, in a ranging system using a SPAD, a back-illuminated sensor element having a laminated structure in which a sensor substrate provided with a SPAD and a logic substrate provided with a logic circuit are bonded together, and irradiated with light from a back surface side of a semiconductor substrate is adopted. In the sensor element having such a device structure, in a case where an area of the sensor substrate is reduced as the pixel size is reduced in the future, the logic substrate also needs to have a small area. In this case, the number of transistors that can be formed on the logic substrate is limited, and as a result, there is a concern that the function of the logic circuit is reduced. Note that, in the flat structure in which the pixel and the logic circuit are formed on the same semiconductor substrate, the function of the logic circuit is not reduced even if the pixel size is reduced, but the fill factor is limited.

Therefore, in the sensor element having the laminated structure, it is required to develop a small and highly functional sensor element while avoiding reduction in the function of the logic circuit even if the pixel size is reduced.

The present disclosure has been made in view of such a situation, and it is an object of the present disclosure to achieve further downsizing and high functionality.

### Solutions to Problems

A sensor element according to one aspect of the present disclosure includes: a sensor substrate in which a single photon avalanche diode (SPAD) is provided on a semiconductor substrate for each pixel; a logic substrate laminated on the sensor substrate and provided with a logic circuit; and a plurality of transistors used to output a signal according to a cathode voltage or an anode voltage of the SPAD, in which at least some of the plurality of the transistors are provided in a well formed in the semiconductor substrate of the sensor substrate.

A ranging system according to one aspect of the present disclosure includes: a lighting device that emits irradiation light; and a sensor element that detects reflected light with respect to the irradiation light, in which the sensor element includes: a sensor substrate in which a SPAD is provided on a semiconductor substrate for each pixel; a logic substrate laminated on the sensor substrate and provided with a logic circuit; and a plurality of transistors used to output a signal according to a cathode voltage or an anode voltage of the SPAD, and at least some of the plurality of the transistors are provided in a well formed in the semiconductor substrate of the sensor substrate.

In one aspect of the present disclosure, a sensor substrate in which a SPAD is provided on a semiconductor substrate for each pixel and a logic substrate in which a logic circuit is provided are laminated, and at least some of a plurality of transistors used to output a signal according to a cathode voltage or an anode voltage of the SPAD are provided in a well formed in the semiconductor substrate of the sensor substrate.

### BRIEF DESCRIPTION OF DRAWINGS

FIG. 1 is a cross-sectional view illustrating a configuration example of a first embodiment of a sensor element to which the present technology is applied.

FIG. 2 is a diagram illustrating an example of a planar layout of the sensor element in FIG. 1.

FIG. 3 is a diagram illustrating an example of a circuit diagram of the sensor element of FIG. 1.

FIG. 4 is a diagram for explaining an operation of a SPAD.

FIG. 5 is a cross-sectional view illustrating a configuration example of a second embodiment of a sensor element to which the present technology is applied.

FIG. 6 is a diagram illustrating an example of a planar layout of the sensor element in FIG. 5.

FIG. 7 is a diagram illustrating an example of a circuit diagram of the sensor element of FIG. 5.

FIG. 8 is a cross-sectional view illustrating a configuration example of a third embodiment of a sensor element to which the present technology is applied.

FIG. 9 is a diagram illustrating an example of a planar layout of the sensor element in FIG. 8.

FIG. 10 is a diagram illustrating an example of a circuit diagram of the sensor element of FIG. 8.

FIG. 11 is a cross-sectional view illustrating a configuration example of a fourth embodiment of a sensor element to which the present technology is applied.

FIG. 12 is a diagram illustrating an example of a planar layout of the sensor element in FIG. 11.

FIG. 13 is a diagram illustrating an example of a circuit diagram of the sensor element in FIG. 11.

FIG. 14 is a cross-sectional view illustrating a configuration example of a fifth embodiment of a sensor element to which the present technology is applied.

FIG. 15 is a diagram illustrating an example of a planar layout of the sensor element in FIG. 14.

FIG. 16 is a cross-sectional view illustrating a configuration example of a sixth embodiment of a sensor element to which the present technology is applied.

FIG. 17 is a diagram illustrating an example of a planar layout of the sensor element in FIG. 16.

FIG. 18 is a cross-sectional view illustrating a configuration example of a seventh embodiment of a sensor element to which the present technology is applied.

FIG. 19 is a diagram illustrating an example of a planar layout of the sensor element in FIG. 18.

FIG. 20 is a cross-sectional view illustrating a configuration example of an eighth embodiment of a sensor element to which the present technology is applied.

FIG. 21 is a cross-sectional view illustrating a configuration example of the eighth embodiment of the sensor element to which the present technology is applied.

FIG. 22 is a diagram illustrating an example of a planar layout of the sensor element in FIGS. 20 and 21.

FIG. 23 is a diagram illustrating an example of a circuit diagram of the sensor element in FIGS. 20 and 21.

FIG. 24 is a block diagram illustrating a configuration example of an embodiment of a ranging system to which the present technology is applied.

FIG. 25 is a diagram illustrating a usage example to use an image sensor.

### MODE FOR CARRYING OUT THE INVENTION

Hereinafter, specific embodiments to which the present technology is applied will be described in detail with reference to the drawings.

### <First Configuration Example of Sensor Element>

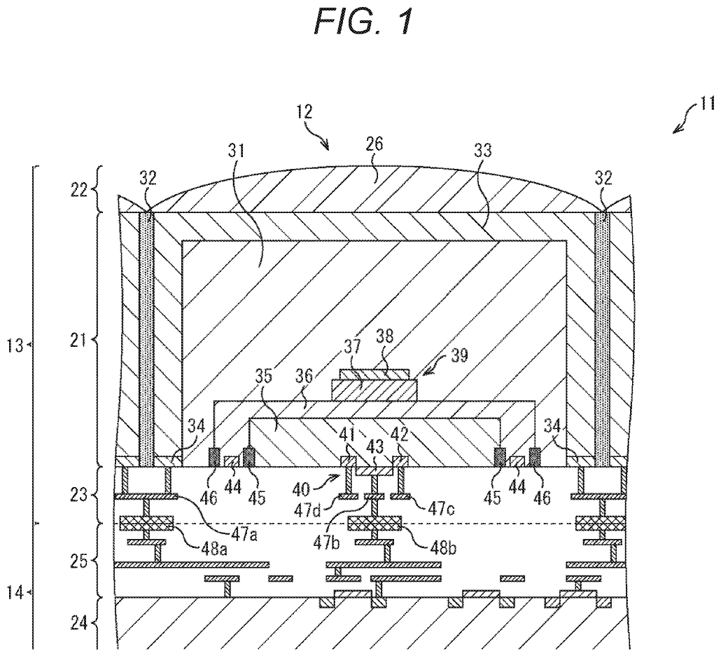

A first embodiment of a sensor element to which the present technology is applied will be described with reference to FIGS. 1 to 4.

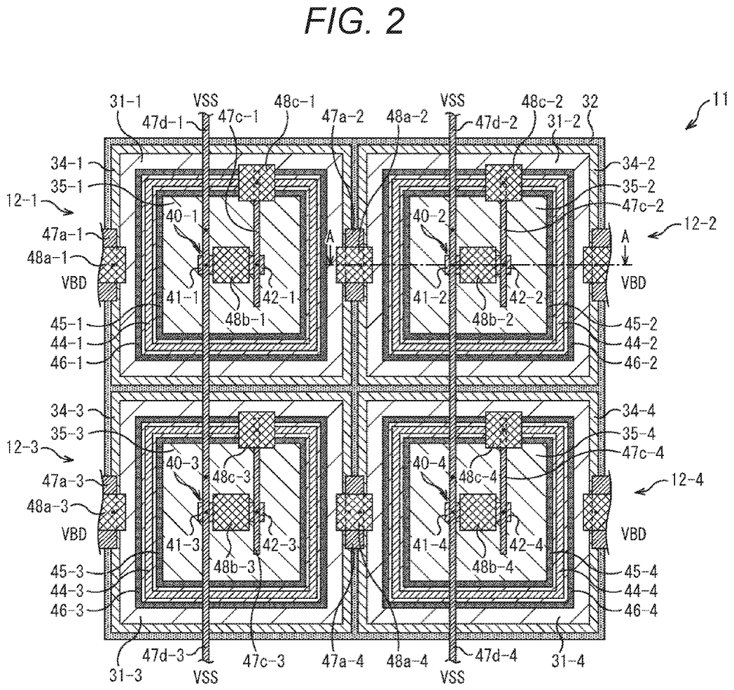

FIG. 1 illustrates an example of a cross-sectional configuration of a pixel 12 included in a sensor element 11 according to a first embodiment. The cross-sectional configuration of the pixel 12 illustrated in FIG. 1 corresponds to a cross section along an arrow A-A illustrated in a planar layout of FIG. 2.

As illustrated in FIG. 1, the sensor element 11 has a two-layer structure in which a sensor substrate 13 provided with a SPAD 39 for each pixel 12 and a logic substrate 14 provided with a logic circuit are laminated by being joined at a joint surface illustrated by a broken line. The sensor substrate 13 is configured by laminating an on-chip lens layer 22 on an upper surface (back surface) of a semiconductor substrate 21 and laminating a wiring layer 23 on a lower surface (front surface) of the semiconductor substrate 21. The logic substrate 14 is configured by laminating a wiring layer 25 on an upper surface of a semiconductor substrate 24. In the on-chip lens layer 22, a microlens 26 is provided for each pixel 12.

The pixel 12 is configured such that a well layer 31 of the semiconductor substrate 21 is electrically isolated from the well layer 31 of another adjacent pixel 12 by a pixel isolation portion 32, and a hole accumulation region 33 is provided so as to surround a side surface and an upper surface of the well layer 31. The hole accumulation region 33 is a p-type semiconductor region for accumulating holes, and an anode region 34, which is a P-type region having a p-type impurity concentration higher than that of the hole accumulation region 33, is provided on the lower surface side of the semiconductor substrate 21 corresponding to the region where the hole accumulation region 33 is formed.

The pixel 12 is configured such that a P-well 35 which is a p-type semiconductor region is provided on a lower surface side of the semiconductor substrate 21, and an N-well 36 which is an n-type semiconductor region is provided so as to surround a side surface and an upper surface of the P-well 35. Then, in the pixel 12, the SPAD 39 is formed in a pn junction region of a N-type multiplication region 37 and a P-type multiplication region 38 provided so as to be laminated on an upper surface of the N-well 36. The SPAD 39 is a photodiode (single photon avalanche photodiode) in which a cathode potential drops due to a current flowing by avalanche amplification of electrons generated in response to incidence of light on the pixel 12.

The pixel 12 is configured such that an NMOS transistor 40 used to output a signal according to a cathode voltage of the SPAD 39 is provided on the lower surface of the semiconductor substrate 21 in the region where the P-well 35 is formed. The NMOS transistor 40 is configured such that a gate electrode 43 is provided between a source region 41 and a drain region 42, which are N-type regions provided for the P-well 35, so as to be laminated on the semiconductor substrate 21 via an insulating film.

The pixel 12 is configured such that a cathode region 44 having an n-type impurity concentration higher than that of the N-well 36 is provided on a lower surface side of the semiconductor substrate 21 corresponding to the region where the N-well 36 is formed. Furthermore, a separation portion 45 is provided at a boundary between the P-well 35 and the N-well 36, and a separation portion 46 is provided at a boundary between the well layer 31 and the N-well 36. The separation portions 45 and 46 are formed by, for example, embedding an insulator such as an oxide film in a trench formed by shallowly carving the lower surface of the semiconductor substrate 21.

The separation portion 45 separates the P-well 35 and the N-well 36 from each other in the vicinity of the surface of the semiconductor substrate 21. The separation portion 46 separates the cathode region 44 provided in the vicinity of the surface of the semiconductor substrate 21 of the N-well 36 from the anode region 34 provided in the vicinity of the surface of the semiconductor substrate 21 along an outer periphery of the pixel 12. Note that the separation portion 46 may be provided at any position as long as the anode region 34 and the cathode region 44 can be separated, and is not limited to a position of the boundary between the well layer 31 and the N-well 36 as illustrated.

A plurality of metal wirings 47 is arranged in the wiring layer 23, and electrical and mechanical connection is performed by a plurality of Cu—Cu connection portions 48 on a connection surface between the wiring layer 23 and the wiring layer 25.

For example, a metal wiring 47a is provided so as to connect the anode regions 34 of the adjacent pixels 12, and is connected to a breakdown power supply (VBD) on a side of the logic substrate 14 via a Cu—Cu connection portion 48a. The breakdown power supply is a power supply that supplies a breakdown voltage at which avalanche multiplication starts. A metal wiring 47b is provided between the gate electrode 43 of the NMOS transistor 40 and a Cu—Cu connection portion 48b, and a drive signal for driving the NMOS transistor 40 is supplied from the logic substrate 14. A metal wiring 47c is connected to the drain region 42 of the NMOS transistor 40, and is connected to the logic substrate 14 via a Cu—Cu connection portion 48c as illustrated in FIG. 2 as described later. A metal wiring 47d is connected to the source region 41 of the NMOS transistor 40, and is connected to a VSS power supply as illustrated in FIG. 2 as described later.

FIG. 2 illustrates an example of a planar layout of four pixels 12-1 to 12-4 included in the sensor element 11 according to the first embodiment. Note that, as illustrated in FIG. 2, the pixels 12-1 to 12-4 are similarly configured, and are simply referred to as pixels 12 in a case where it is not necessary to distinguish them.

For example, the sensor element 11 is configured such that the P-well 35 is formed for each pixel 12 and the NMOS transistor 40 is provided in the P-well 35. Furthermore, the separation portion 45 separates the P-well 35 from the cathode region 44 provided so as to surround the outer periphery of the P-well 35, and the separation portion 46 separates the cathode region 44 from the anode region 34 provided so as to surround the outer periphery of the well layer 31.

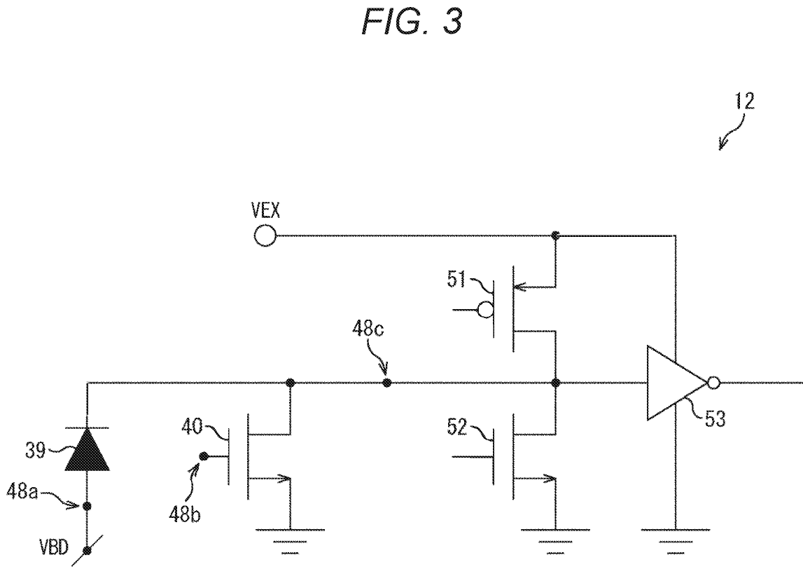

FIG. 3 illustrates an example of a circuit diagram of the pixel 12.

The pixel 12 is configured by connecting the SPAD 39, the NMOS transistor 40, a PMOS transistor 51 for quenching or recharging, an NMOS transistor 52 for deactivating the SPAD 39, and an inverter 53.

As described with reference to FIGS. 1 and 2, the SPAD 39 and the NMOS transistor 40 are formed on the sensor substrate 13. On the other hand, the PMOS transistor 51, the NMOS transistor 52, and the inverter 53 are formed in the logic substrate 14, and a breakdown power supply, an excess bias power supply (VEX), and the like are also supplied from the logic substrate 14 to the sensor substrate 13. The excess bias power supply is a power supply that supplies an excess bias voltage exceeding a breakdown voltage. Therefore, the sensor substrate 13 and the logic substrate 14 are connected via the Cu—Cu connection portions 48a to 48c.

The Cu—Cu connection portion 48a connects the anode of the SPAD 39 and the breakdown power supply. The Cu—Cu connection portion 48b connects the gate of the NMOS transistor 40 to a side of the logic substrate 14. The Cu—Cu connection portion 48c connects the cathode of the SPAD 39 and the drain of the NMOS transistor 40, and an input terminal of the inverter 53.

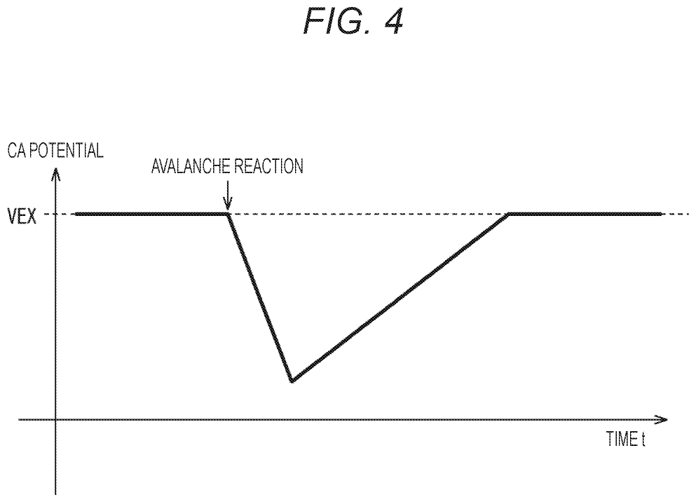

The operation of the SPAD 39 will be described with reference to FIG. 4. In FIG. 4, the vertical axis represents a cathode potential of the SPAD 39, and the horizontal axis represents a passage of time.

For example, the anode of the SPAD 39 is connected to a breakdown power supply for applying a reverse voltage larger than a breakdown voltage of the SPAD 39, and an excess bias voltage power supply is supplied to the cathode of the SPAD 39 via the PMOS transistor 51. Then, when photons are incident on the SPAD 39, avalanche amplification occurs, and a current flows through the SPAD 39 at that timing, so that a voltage drop occurs. By monitoring a potential fluctuation when the SPAD 39 performs the avalanche reaction in this manner, the sensor element 11 can detect incidence of photons for each pixel 12.

The sensor element 11 is configured as described above, and by providing the NMOS transistor 40 on a side of the sensor substrate 13, further downsizing and high functionality can be achieved. For example, even if the sensor element 11 shrinks the pixel size to reduce the chip size, an occupied area of the transistor in the logic substrate 14 can be reduced by an amount of the NMOS transistor 40 provided on the side of the sensor substrate 13. As a result, it is possible to avoid reduction in the function of the logic circuit provided on the logic substrate 14, and as a result, it is possible to realize the small and highly functional sensor element 11.

Furthermore, the sensor element 11 has a configuration in which the P-well 35 and the N-well 36 in the vicinity of a surface of the semiconductor substrate 21 are separated by the separation portion 45 and the anode region 34 and the cathode region 44 are separated by the separation portion 46, whereby the pressure resistance can be further improved. As a result, the performance of the sensor element 11 can be improved.

### <Second Configuration Example of Sensor Element>

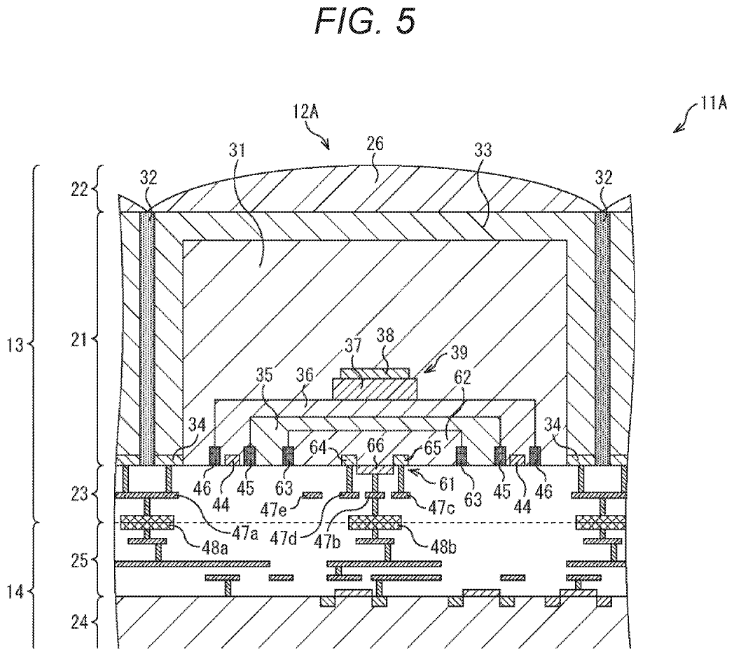

A second embodiment of a sensor element to which the present technology is applied will be described with reference to FIGS. 5 to 7. Note that, in a sensor element 11A and a pixel 12A illustrated in FIGS. 5 to 7, configurations common to the sensor element 11 and the pixel 12 in FIGS. 1 to 3 are denoted by the same reference signs, and a detailed description thereof will be omitted.

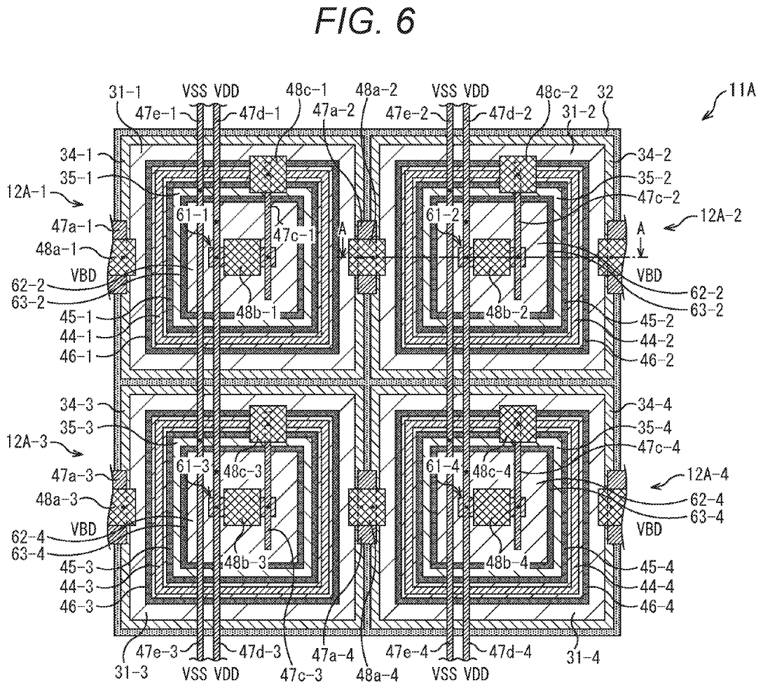

FIG. 5 illustrates an example of a cross-sectional configuration of the pixel 12A included in the sensor element 11A according to the second embodiment. The cross-sectional configuration of the pixel 12A illustrated in FIG. 5 corresponds to a cross section along an arrow A-A illustrated in a planar layout of FIG. 6.

The pixel 12A is different from the pixel 12 in FIG. 1 in that a PMOS transistor 61 is provided on the lower surface of the semiconductor substrate 21. In the pixel 12A, an N-well 62, which is an n-type semiconductor region, is provided on the lower surface side of the semiconductor substrate 21 in order to provide the PMOS transistor 61. A side surface and an upper surface of the N-well 62 are surrounded by the P-well 35, and a separation portion 63 is provided at a boundary between the P-well 35 and the N-well 62. The separation portion 63 separates the P-well 35 and the N-well 62 from each other in the vicinity of the surface of the semiconductor substrate 21. Furthermore, similarly to the pixel 12 in FIG. 1, the separation portions 45 and 46 are also provided.

The PMOS transistor 61 is configured such that a gate electrode 66 is provided between a source region 65 and a drain region 64, which are P-type regions provided for the N-well 62, so as to be laminated on the semiconductor substrate 21 via an insulating film.

A metal wiring 47c is connected to the source region 65 of the PMOS transistor 61, and is connected to the logic substrate 14 via the Cu—Cu connection portion 48c as illustrated in FIG. 6 as described later. A metal wiring 47d is connected to the drain region 64 of the PMOS transistor 61, and is connected to a VDD power supply as illustrated in FIG. 6 as described later. A metal wiring 47e is connected to the VSS power supply as illustrated in FIG. 6 as described later.

FIG. 6 illustrates an example of a planar layout of four pixels 12A-1 to 12A-4 included in the sensor element 11A according to the second embodiment. Note that, as illustrated in FIG. 6, the pixels 12A-1 to 12A-4 are similarly configured, and are simply referred to as pixels 12A in a case where it is not necessary to distinguish them.

For example, the sensor element 11A is configured such that the N-well 62 is formed for each pixel 12A, and the PMOS transistor 61 is provided in the N-well 62. Furthermore, the N-well 62 and the P-well 35 provided so as to surround the N-well 62 are separated by the separation portion 63.

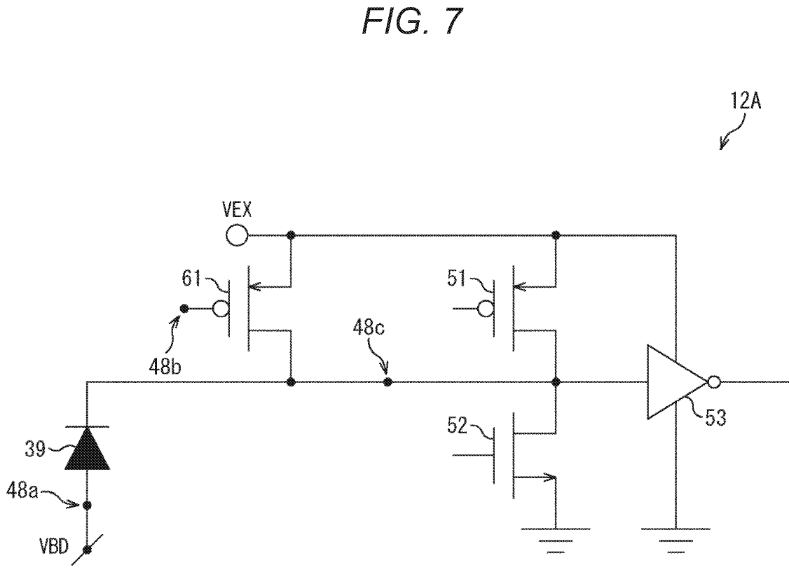

FIG. 7 illustrates an example of a circuit diagram of the pixel 12A.

The pixel 12A is configured by connecting the SPAD 39, the PMOS transistor 61, the PMOS transistor 51 for quenching or recharging, the NMOS transistor 52 for deactivating the SPAD 39, and the inverter 53.

As described with reference to FIGS. 5 and 6, the SPAD 39 and the PMOS transistor 61 are formed on the sensor substrate 13. On the other hand, the PMOS transistor 51, the NMOS transistor 52, and the inverter 53 are formed in the logic substrate 14, and a breakdown power supply, an excess bias power supply, and the like are also supplied from the logic substrate 14 to the sensor substrate 13. Therefore, the sensor substrate 13 and the logic substrate 14 are connected via the Cu—Cu connection portions 48a to 48c.

The Cu—Cu connection portion 48a connects the anode of the SPAD 39 and the breakdown power supply. The Cu—Cu connection portion 48b connects the gate of the PMOS transistor 61 to the side of the logic substrate 14. The Cu—Cu connection portion 48c connects the cathode of the SPAD 39 and the source of the PMOS transistor 61, and the input terminal of the inverter 53.

The sensor element 11A is configured as described above, and by providing the PMOS transistor 61 on the side of the sensor substrate 13 of the pixel 12A, similarly to the sensor element 11 described above, downsizing and high functionality can be achieved.

### <Third Configuration Example of Sensor Element>

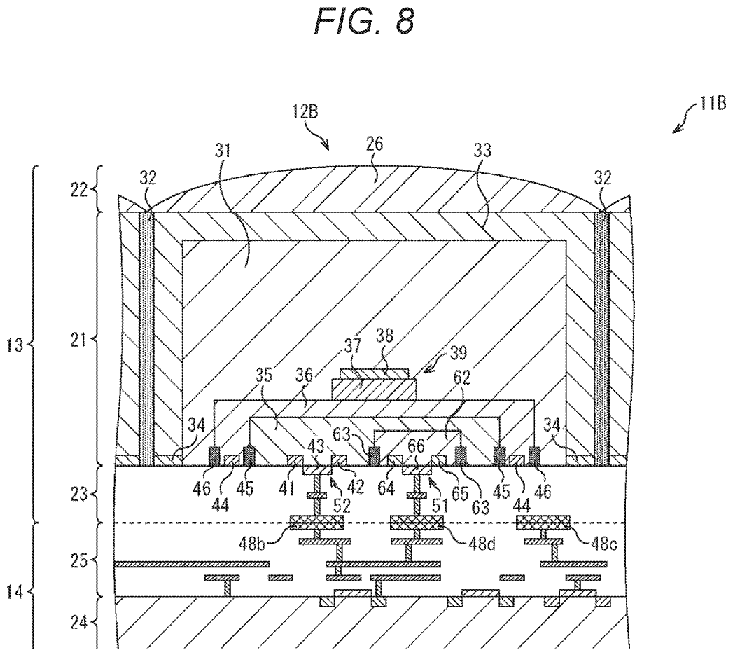

A third embodiment of a sensor element to which the present technology is applied will be described with reference to FIGS. 8 to 10. Note that, in a sensor element 11B and a pixel 12B illustrated in FIGS. 8 to 10, configurations common to the sensor element 11 and the pixel 12 in FIGS. 1 to 3 are denoted by the same reference signs, and a detailed description thereof is omitted.

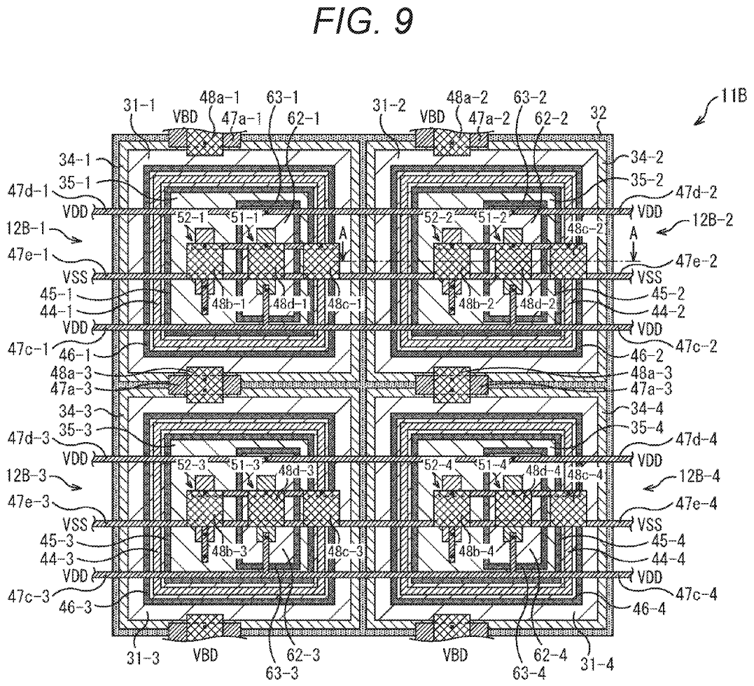

FIG. 8 illustrates an example of a cross-sectional configuration of the pixel 12B included in the sensor element 11B according to the third embodiment. The cross-sectional configuration of the pixel 12B illustrated in FIG. 8 corresponds to a cross section along an arrow A-A illustrated in a planar layout of FIG. 9.

The pixel 12B is different from the pixel 12 in FIG. 1 in that the PMOS transistor 51 for quenching or recharging and the NMOS transistor 52 for deactivating the SPAD 39 are provided on the semiconductor substrate 21.

In the pixel 12B, the NMOS transistor 52 is provided in the P-well 35, and the N-well 62 is provided in an approximately half region of the P-well 35 in order to provide the PMOS transistor 51. A side surface and an upper surface of the N-well 62 are surrounded by the P-well 35, and a separation portion 63 is provided at a boundary between the P-well 35 and the N-well 62. The separation portion 63 separates the P-well 35 and the N-well 62 from each other in the vicinity of the surface of the semiconductor substrate 21. Furthermore, similarly to the pixel 12 in FIG. 1, the separation portions 45 and 46 are also provided.

The PMOS transistor 51 is configured such that the gate electrode 66 is provided between the source region 65 and the drain region 64, which are P-type regions provided for the N-well 62, so as to be laminated on the semiconductor substrate 21 via an insulating film. The NMOS transistor 52 is configured such that the gate electrode 43 is provided between the source region 41 and the drain region 42, which are N-type regions provided for the P-well 35, so as to be laminated on the semiconductor substrate 21 via an insulating film.

FIG. 9 illustrates an example of a planar layout of four pixels 12B-1 to 12B-4 included in the sensor element 11B according to the third embodiment. Note that, as illustrated in FIG. 9, the pixels 12B-1 to 12B-4 are similarly configured, and are simply referred to as the pixel 12B in a case where it is not necessary to distinguish them.

For example, in the sensor element 11B, the P-well 35 is formed for each pixel 12B, and the N-well 62 is formed in a substantially half region in the P-well 35. Then, the sensor element 11B is configured such that the PMOS transistor 51 is provided in the N-well 62 and the NMOS transistor 52 is provided in the P-well 35. Furthermore, the N-well 62 and the P-well 35 provided so as to surround the N-well 62 are separated by the separation portion 63.

A metal wiring 47c is connected to the drain region 64 of the PMOS transistor 51, and is connected to a VDD power supply. A metal wiring 47e is connected to the source region 41 of the NMOS transistor 52, and is connected to a VSS power supply. The metal wiring 47d is connected to the N-well 62, and is connected to a VDD power supply.

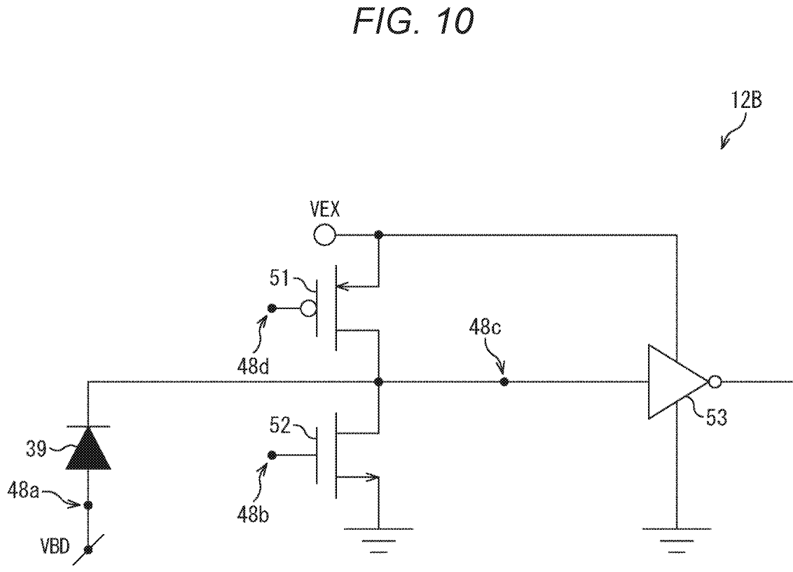

FIG. 10 illustrates an example of a circuit diagram of the pixel 12B.

The pixel 12B is configured by connecting the SPAD 39, the PMOS transistor 51 for quenching or recharging, the NMOS transistor 52 for deactivating the SPAD 39, and the inverter 53.

As described with reference to FIGS. 8 and 9, the SPAD 39, the PMOS transistor 51, and the NMOS transistor 52 are formed in the sensor substrate 13. On the other hand, the inverter 53 is formed on the logic substrate 14, and a breakdown power supply, an excess bias power supply, and the like are also supplied from the logic substrate 14 to the sensor substrate 13. Therefore, the sensor substrate 13 and the logic substrate 14 are connected via the Cu—Cu connection portions 48a to 48d.

The Cu—Cu connection portion 48a connects the anode of the SPAD 39 and the breakdown power supply. The Cu—Cu connection portion 48b connects the gate of the NMOS transistor 52 to the side of the logic substrate 14. The Cu—Cu connection portion 48c connects the cathode of the SPAD 39 and the input terminal of the inverter 53. The Cu—Cu connection portion 48d connects the gate of the PMOS transistor 51 to the side of the logic substrate 14.

The sensor element 11B is configured as described above, and by providing the PMOS transistor 51 and the NMOS transistor 52 on the side of the sensor substrate 13 of the pixel 12B, similarly to the sensor element 11 described above, downsizing and high functionality can be achieved.

Note that the arrangement of the PMOS transistor 51 and the NMOS transistor 52, the layout of the metal wiring 47, and the like are not limited to the arrangement and layout illustrated in FIG. 9, and are only required to be any arrangement and layout that realize the wiring of the circuit diagram illustrated in FIG. 10.

### <Fourth Configuration Example of Sensor Element>

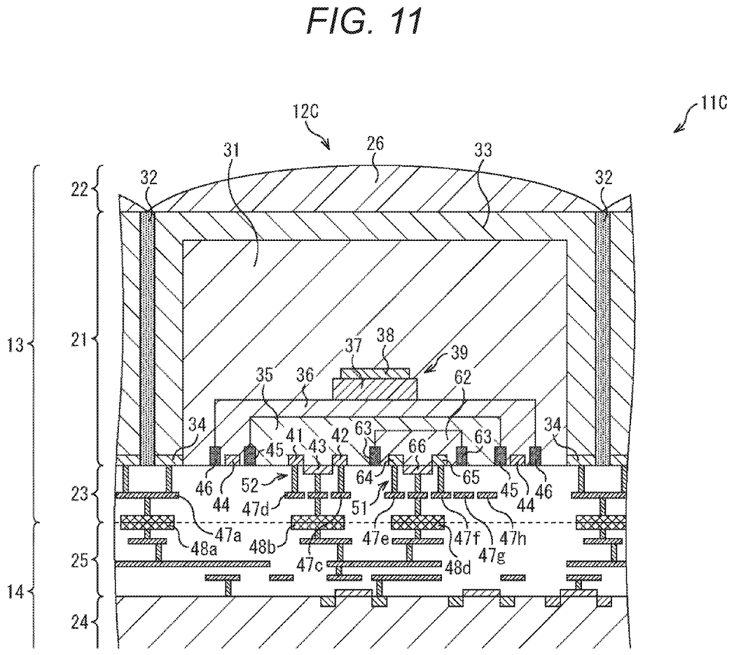

A fourth embodiment of a sensor element to which the present technology is applied will be described with reference to FIGS. 11 to 13. Note that, in a sensor element 11C and a pixel 12C illustrated in FIGS. 11 to 13, configurations common to the sensor element 11 and the pixel 12 in FIGS. 1 to 3 are denoted by the same reference signs, and detailed description thereof is omitted.

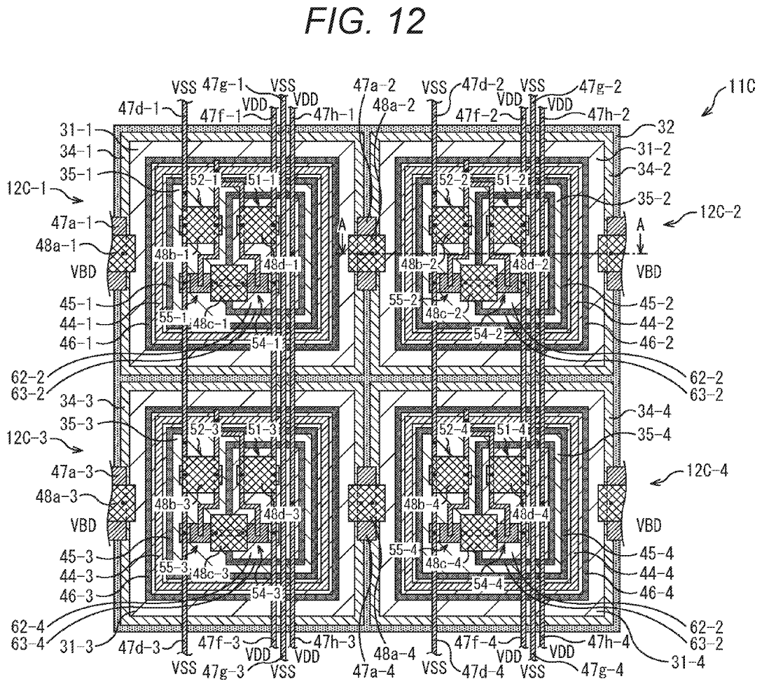

FIG. 11 illustrates an example of a cross-sectional configuration of the pixel 12C included in the sensor element 11C according to the fourth embodiment. The cross-sectional configuration of the pixel 12C illustrated in FIG. 11 corresponds to a cross section along an arrow A-A illustrated in a planar layout of FIG. 12.

The pixel 12C is different from the pixel 12 in FIG. 1 in that the PMOS transistor 51 for quenching or recharging and the NMOS transistor 52 for deactivating the SPAD 39 are provided on the semiconductor substrate 21. Moreover, the pixel 12C is different from the pixel 12 in FIG. 1 in that the PMOS transistor 54 and the NMOS transistor 55 constituting the inverter 53 are provided on the semiconductor substrate 21 as illustrated in FIG. 12 as described later.

In the pixel 12C, the NMOS transistor 52 and the NMOS transistor 55 are provided in the P-well 35. In the pixel 12C, in order to provide the PMOS transistor 51 and the PMOS transistor 54, the N-well 62 is provided in a substantially half region of the P-well 35. A side surface and an upper surface of the N-well 62 are surrounded by the P-well 35, and a separation portion 63 is provided at a boundary between the P-well 35 and the N-well 62. The separation portion 63 separates the P-well 35 and the N-well 62 from each other in the vicinity of the surface of the semiconductor substrate 21. Furthermore, similarly to the pixel 12 in FIG. 1, the separation portions 45 and 46 are also provided.

The PMOS transistor 51 is configured such that the gate electrode 66 is provided between the source region 65 and the drain region 64, which are P-type regions provided for the N-well 62, so as to be laminated on the semiconductor substrate 21 via an insulating film. Note that, although not illustrated, the PMOS transistor 54 is configured similarly to the PMOS transistor 51.

The NMOS transistor 52 is configured such that the gate electrode 43 is provided between the source region 41 and the drain region 42, which are N-type regions provided for the P-well 35, so as to be laminated on the semiconductor substrate 21 via an insulating film. Note that, although not illustrated, the NMOS transistor 55 is configured similarly to the NMOS transistor 52.

FIG. 12 illustrates an example of a planar layout of four pixels 12C-1 to 12C-4 included in the sensor element 11C according to the fourth embodiment. Note that, as illustrated in FIG. 12, the pixels 12C-1 to 12C-4 are similarly configured, and are simply referred to as the pixel 12C in a case where it is not necessary to distinguish them.

For example, the sensor element 11C is configured such that the P-well 35 is formed for each pixel 12C, and the NMOS transistor 52 and the NMOS transistor 55 are provided for the P-well 35. Moreover, the sensor element 11C is configured such that the N-well 62 is formed in a region of approximately half of the P-well 35, and the PMOS transistor 51 and the PMOS transistor 54 are provided for the N-well 62. Furthermore, the N-well 62 and the P-well 35 provided so as to surround the N-well 62 are separated by the separation portion 63.

The sensor element 11C has a layout in which a metal wiring 47g connected to a VSS power supply is arranged between a metal wiring 47f that supplies the VDD power supply to the drain region 64 of the PMOS transistor 51 and the drain region of the PMOS transistor 54 and a metal wiring 47h that supplies the VDD power supply to the N-well 62. By arranging the metal wiring 47g in this manner, it is possible to shield between the adjacent metal wiring 47f and metal wiring 47h. That is, the metal wiring 47g is a shield wiring.

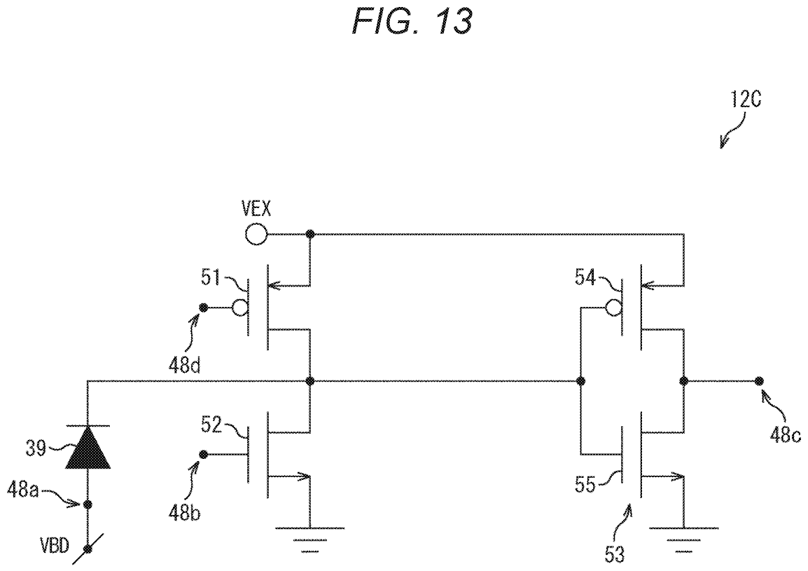

FIG. 13 illustrates an example of a circuit diagram of the pixel 12C.

The pixel 12C is configured by connecting the SPAD 39, the PMOS transistor 51, the NMOS transistor 52, and the PMOS transistor 54 and the NMOS transistor 55 constituting the inverter 53.

As described with reference to FIGS. 11 and 12, the PMOS transistor 51, the NMOS transistor 52, the PMOS transistor 54, and the NMOS transistor 55 are formed on the sensor substrate 13. Therefore, the sensor substrate 13 and the logic substrate 14 are connected via the Cu—Cu connection portions 48a to 48d.

The Cu—Cu connection portion 48a connects the anode of the SPAD 39 and the breakdown power supply. The Cu—Cu connection portion 48b connects the gate of the NMOS transistor 52 to the side of the logic substrate 14. The Cu—Cu connection portion 48c connects the output terminal of the inverter 53 to the side of the logic substrate 14. The Cu—Cu connection portion 48d connects the gate of the PMOS transistor 51 to the side of the logic substrate 14.

The sensor element 11C is configured as described above, and the PMOS transistor 51, the NMOS transistor 52, the PMOS transistor 54, and the NMOS transistor 55 are provided on the side of the sensor substrate 13 of the pixel 12C, so that it is possible to further downsize and enhance the functionality similarly to the sensor element 11 described above.

Note that the arrangement of the PMOS transistor 51, the NMOS transistor 52, the PMOS transistor 54, and the NMOS transistor 55, the layout of the metal wiring 47, and the like are not limited to the arrangement and layout illustrated in FIG. 12, and are only required to be any arrangement and layout that realize the wiring of the circuit diagram illustrated in FIG. 13.

### <Fifth Configuration Example of Sensor Element>

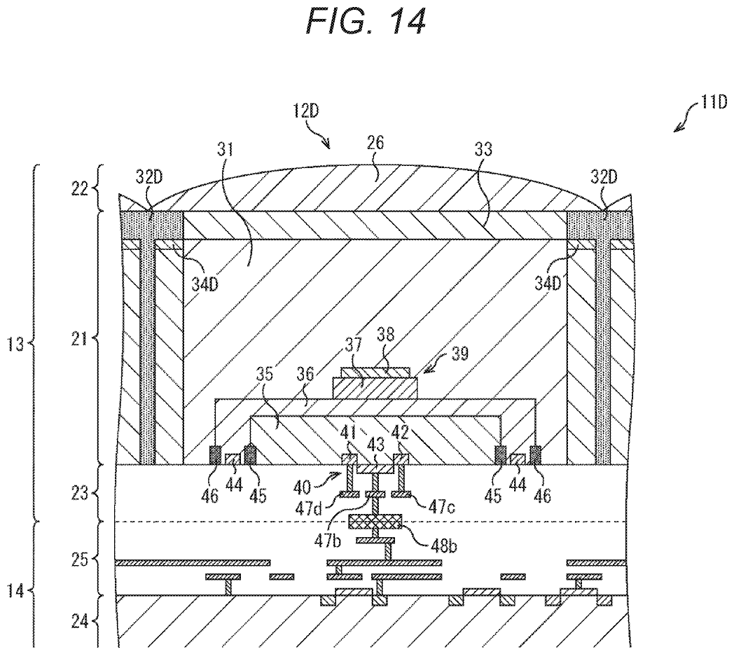

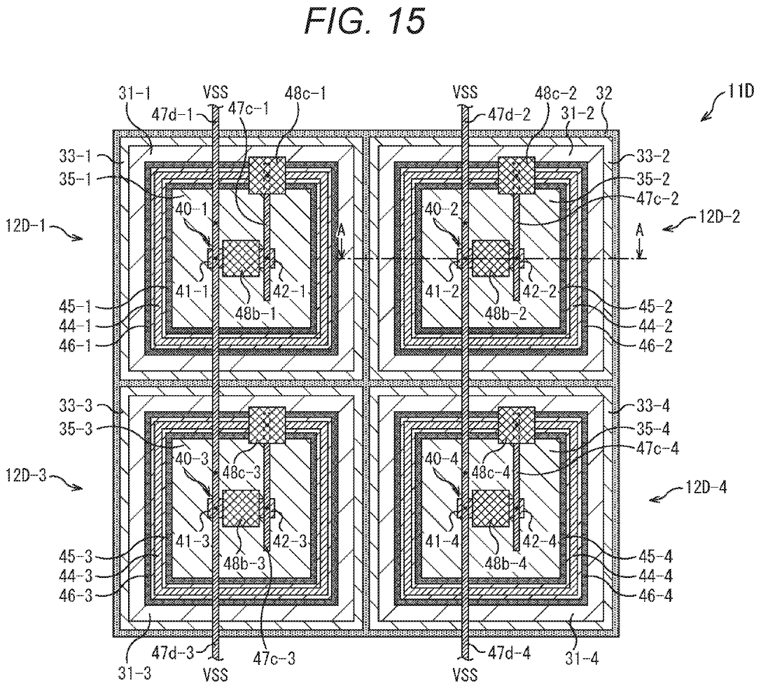

A fifth embodiment of a sensor element to which the present technology is applied will be described with reference to FIGS. 14 and 15. Note that, in a sensor element 11D and a pixel 12D illustrated in FIGS. 14 and 15, configurations common to the sensor element 11 and the pixel 12 in FIGS. 1 and 2 are denoted by the same reference signs, and a detailed description thereof is omitted. Furthermore, a circuit diagram of the pixel 12D is similar to the circuit diagram of the pixel 12 illustrated in FIG. 3.

FIG. 14 illustrates an example of a cross-sectional configuration of the pixel 12D included in the sensor element 11D according to the fifth embodiment. The cross-sectional configuration of the pixel 12D illustrated in FIG. 14 corresponds to a cross section along an arrow A-A illustrated in a planar layout of FIG. 15. FIG. 15 illustrates an example of a planar layout of four pixels 12D-1 to 12D-4. Note that, as illustrated in FIG. 15, the pixels 12D-1 to 12D-4 are similarly configured, and are simply referred to as the pixel 12D in a case where it is not necessary to distinguish them.

The pixel 12D has a configuration different from that of the pixel 12 in FIG. 1 in that a pixel isolation portion 32D is formed in a shape to which an anode voltage can be applied from the back surface side of the semiconductor substrate 21, and an anode region 34D is disposed on the back surface side of the semiconductor substrate 21.

The sensor element 11D configured as described above can improve an edge withstand voltage as compared with a configuration in which an anode voltage is applied from the front surface side of the semiconductor substrate 21 (for example, the sensor element 11 of FIG. 1). Furthermore, the sensor element 11D can have a configuration in which the Cu—Cu connection portion 48a used to apply the anode voltage from the front surface side of the semiconductor substrate 21 is not provided.

The sensor element 11D is configured as described above, and by providing the NMOS transistor 40 on the side of the sensor substrate 13, it is possible to further downsize and enhance the function similarly to the sensor element 11 described above.

### <Sixth Configuration Example of Sensor Element>

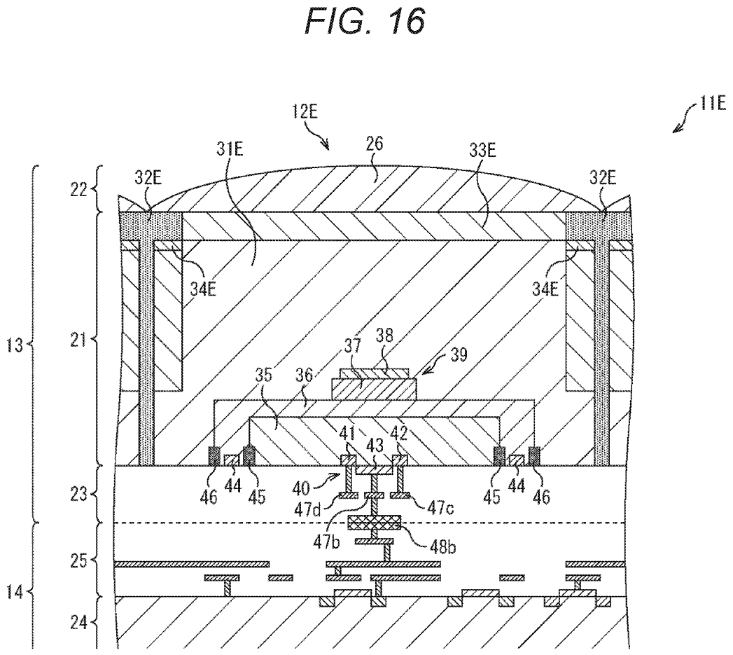

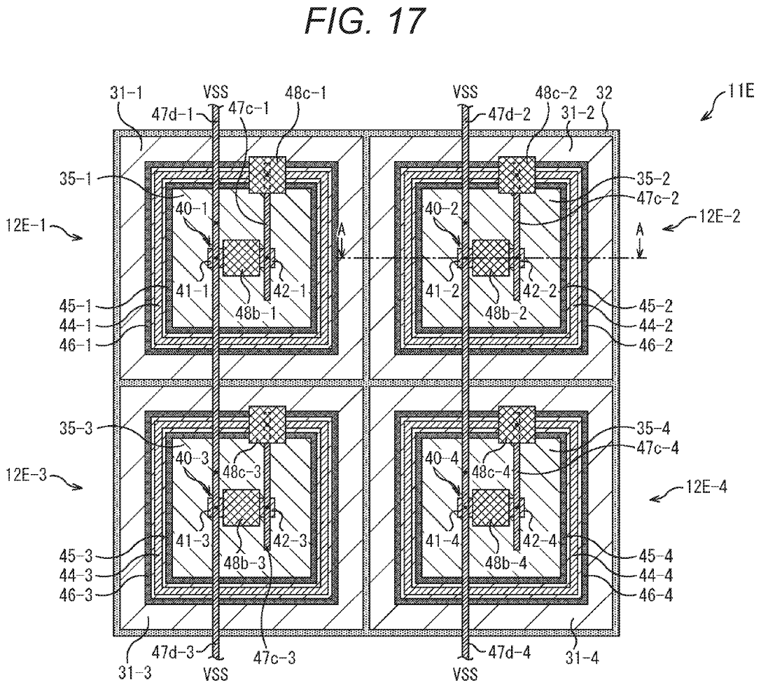

A sensor element according to a sixth embodiment to which the present technology is applied will be described with reference to FIGS. 16 and 17. Note that, in a sensor element 11E and a pixel 12E illustrated in FIGS. 16 and 17, configurations common to the sensor element 11 and the pixel 12 in FIGS. 1 and 2 are denoted by the same reference signs, and a detailed description thereof is omitted. Furthermore, a circuit diagram of the pixel 12E is similar to the circuit diagram of the pixel 12 illustrated in FIG. 3.

FIG. 16 illustrates an example of a cross-sectional configuration of the pixel 12E included in the sensor element 11E according to the sixth embodiment. The cross-sectional configuration of the pixel 12E illustrated in FIG. 16 corresponds to a cross section along an arrow A-A illustrated in a planar layout of FIG. 17. FIG. 17 illustrates an example of a planar layout of four pixels 12E-1 to 12E-4. Note that, as illustrated in FIG. 17, the pixels 12E-1 to 12E-4 are similarly configured, and are simply referred to as the pixel 12E in a case where it is not necessary to distinguish them.

The pixel 12E has a configuration different from that of the pixel 12 in FIG. 1 in that a pixel isolation portion 32E is formed in a shape to which an anode voltage can be applied from the back surface side of the semiconductor substrate 21, and an anode region 34E is disposed on the back surface side of the semiconductor substrate 21.

Moreover, the pixel 12E has a configuration different from that of the pixel 12 in FIG. 1 in that a hole accumulation region 33E is formed in a range deeper than a predetermined depth from the front surface side of the semiconductor substrate 21. For example, the hole accumulation region 33E may be formed in a range deeper than a position where the SPAD 39 is provided, and may not be provided on the side of the SPAD 39.

The sensor element 11E configured as described above can secure a guard ring more than a configuration in which an anode voltage is applied from the front surface side of the semiconductor substrate 21 and the hole accumulation region 33 is provided on the side of the SPAD 39 (for example, the sensor element 11 of FIG. 1). As a result, the sensor element 11E can further improve the edge withstand voltage, for example. Furthermore, the sensor element 11E can have a configuration in which the Cu—Cu connection portion 48a used to apply the anode voltage from the front surface side of the semiconductor substrate 21 is not provided.

### <Seventh Configuration Example of Sensor Element>

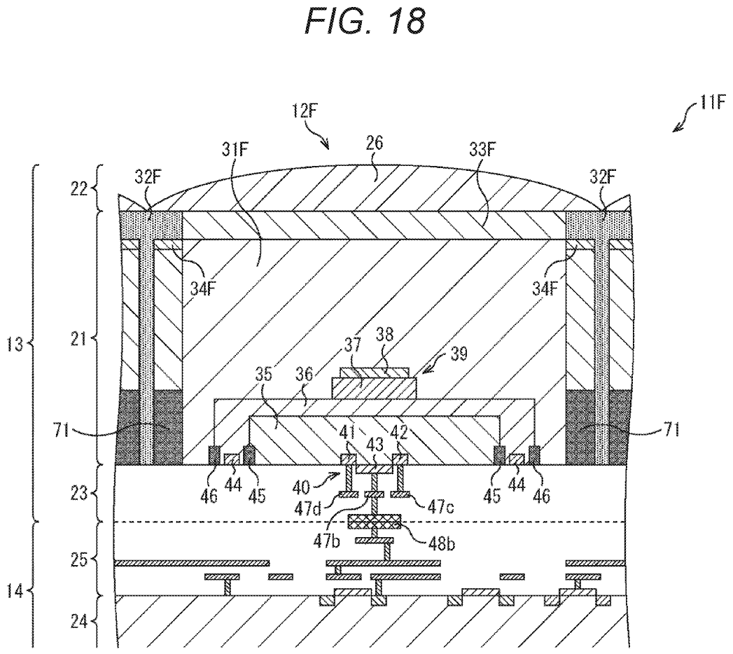

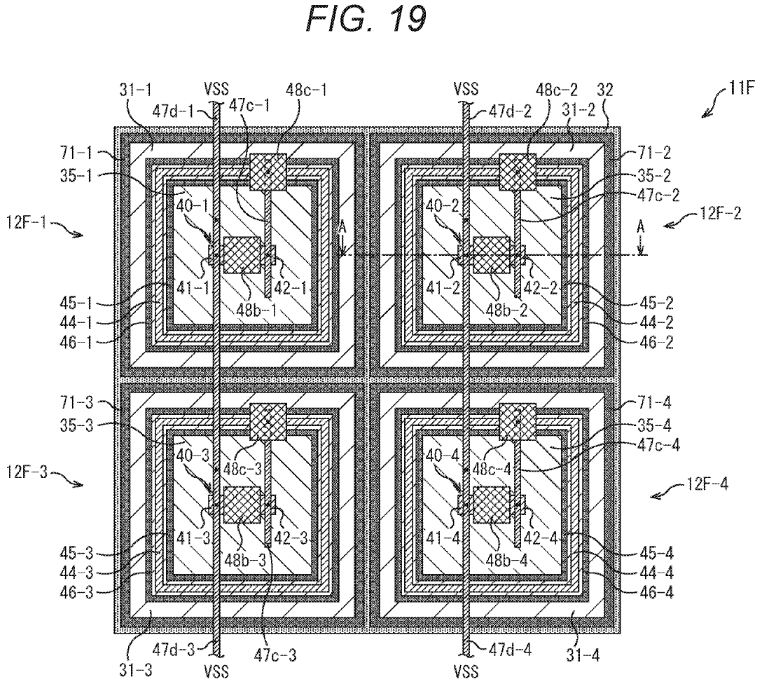

A seventh embodiment of a sensor element to which the present technology is applied will be described with reference to FIGS. 18 and 19. Note that, in a sensor element 11F and a pixel 12F illustrated in FIGS. 18 and 19, configurations common to the sensor element 11 and the pixel 12 in FIGS. 1 and 2 are denoted by the same reference signs, and a detailed description thereof is omitted. Furthermore, a circuit diagram of the pixel 12F is similar to the circuit diagram of the pixel 12 illustrated in FIG. 3.

FIG. 18 illustrates an example of a cross-sectional configuration of the pixel 12F included in the sensor element 11F according to the seventh embodiment. The cross-sectional configuration of the pixel 12F illustrated in FIG. 18 corresponds to a cross section along an arrow A-A illustrated in a planar layout of FIG. 19. FIG. 19 illustrates an example of a planar layout of four pixels 12F-1 to 12F-4. Note that, as illustrated in FIG. 19, the pixels 12F-1 to 12F-4 are similarly configured, and are simply referred to as the pixel 12F in a case where it is not necessary to distinguish them.

The pixel 12F has a configuration different from that of the pixel 12 in FIG. 1 in that a pixel isolation portion 32F is formed in a shape capable of applying an anode voltage from the back surface side of the semiconductor substrate 21, and an anode region 34F is disposed on the back surface side of the semiconductor substrate 21.

Moreover, the pixel 12F is different from the pixel 12 in FIG. 1 in that the hole accumulation region 33F is formed in a range deeper than a predetermined depth from the front surface side of the semiconductor substrate 21, and an oxide film 71 having an insulating property is provided in a range shallower than the predetermined depth. For example, the hole accumulation region 33F may be formed in a range deeper than a position where the SPAD 39 is provided and not provided on the side of the SPAD 39, and the oxide film 71 may be formed in a range where the hole accumulation region 33F is not provided on the side of the SPAD 39.

The sensor element 11F configured as described above can secure a guard ring more than a configuration in which the anode voltage is applied from the front surface side of the semiconductor substrate 21 and the hole accumulation region 33 is provided on the side of the SPAD 39 (for example, the sensor element 11 of FIG. 1). As a result, the sensor element 11F can further improve the edge withstand voltage, for example. Furthermore, the sensor element 11F can have a configuration in which the Cu—Cu connection portion 48a used to apply the anode voltage from the front surface side of the semiconductor substrate 21 is not provided.

### <Eighth Configuration Example of Sensor Element>

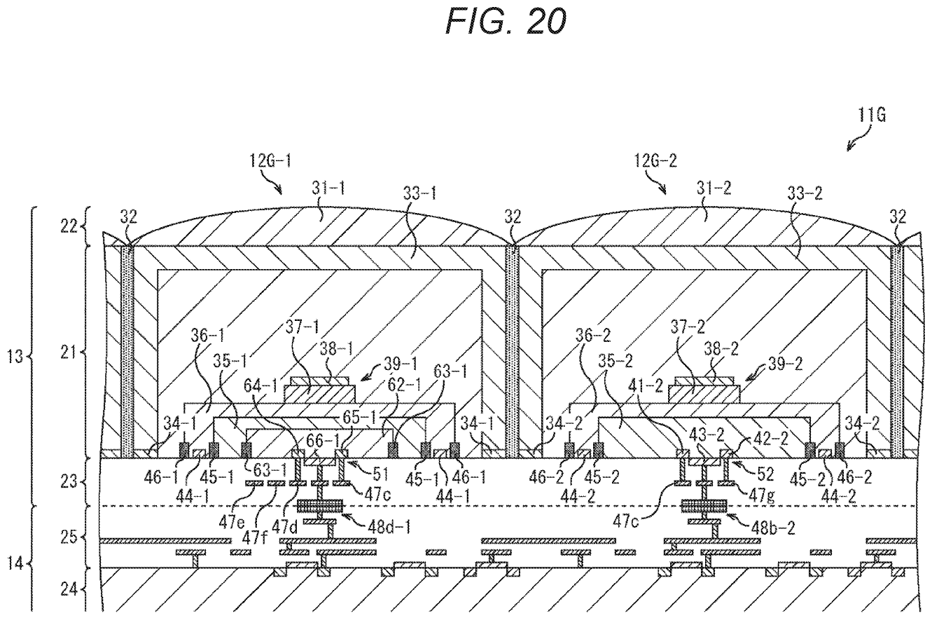

An eighth embodiment of a sensor element to which the present technology is applied will be described with reference to FIGS. 20 to 23. Note that, in a sensor element 11G and a pixel 12G illustrated in FIGS. 20 to 23, configurations common to the sensor element 11 and the pixel 12 in FIGS. 1 to 3 are denoted by the same reference signs, and detailed description thereof is omitted.

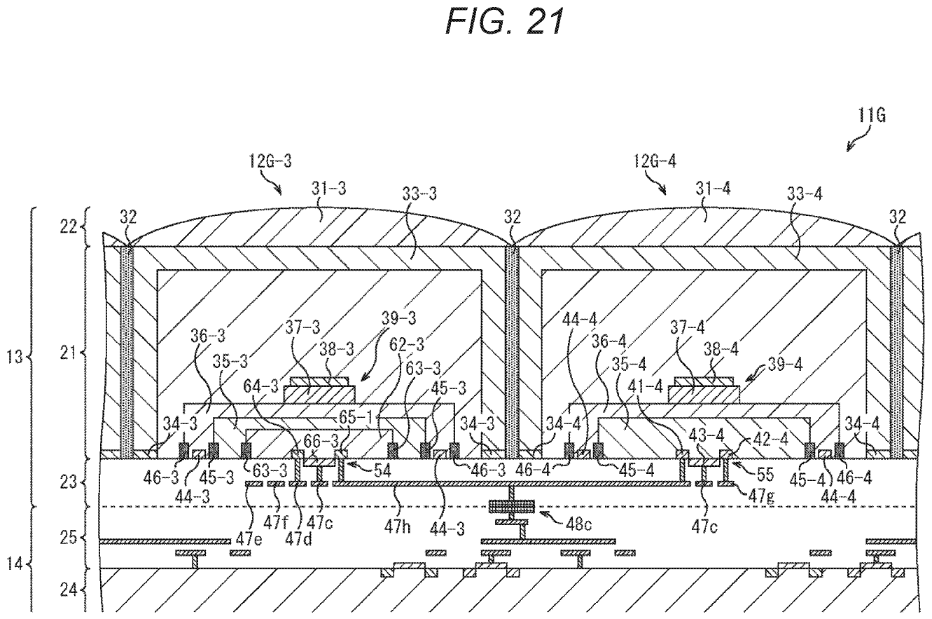

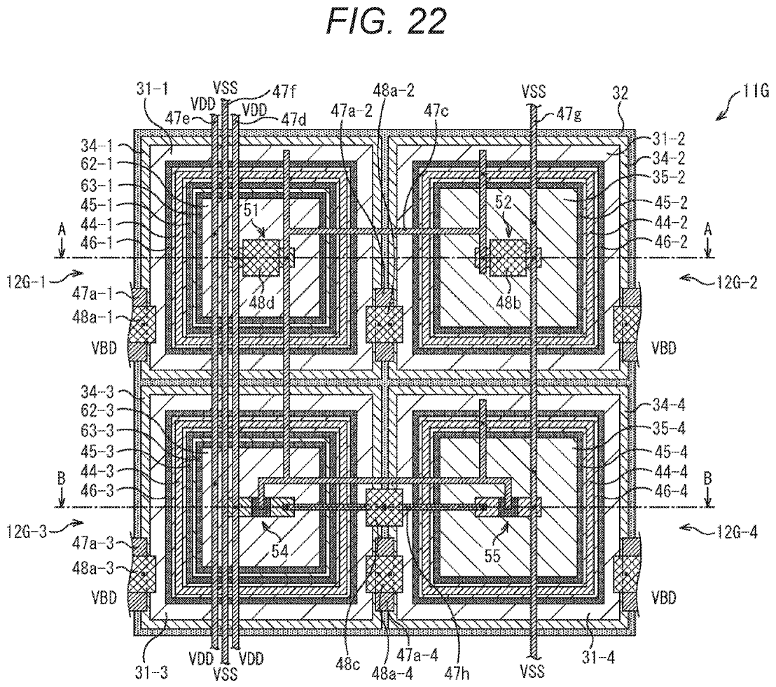

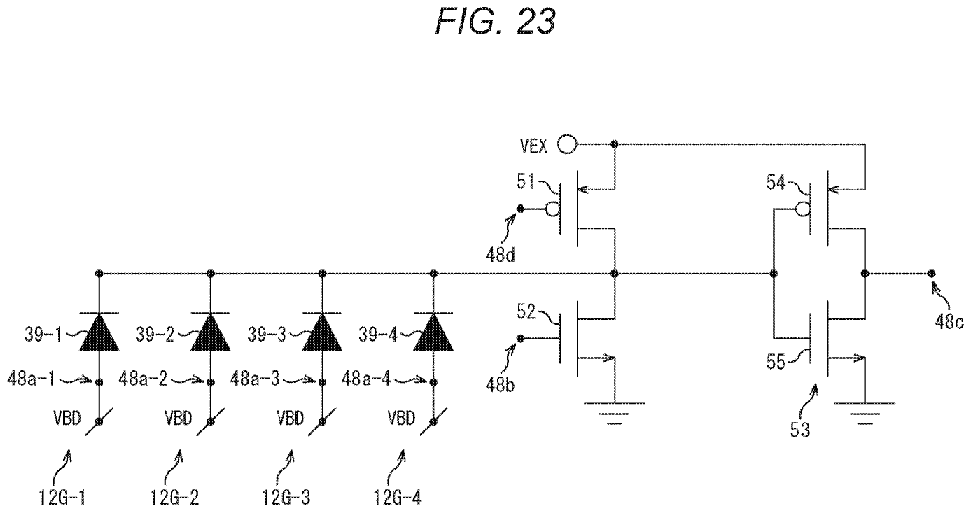

FIGS. 20 and 21 illustrate an example of a cross-sectional configuration of the pixel 12G included in the sensor element 11G according to the eighth embodiment. The cross-sectional configuration of the pixel 12G illustrated in FIG. 20 corresponds to a cross section along an arrow A-A illustrated in a planar layout of FIG. 22, and the cross-sectional configuration of the pixel 12 illustrated in FIG. 21 corresponds to a cross section along an arrow B-B illustrated in FIG. 22. FIG. 22 illustrates an example of a planar layout of four pixels 12G-1 to 12G-4 included in the sensor element 11G. FIG. 23 illustrates an example of a circuit diagram of the pixel 12G.

As illustrated in FIG. 20, the pixel 12G-1 has a configuration in which the PMOS transistor 51 for quenching or recharging is provided on the semiconductor substrate 21, and the pixel 12G-2 has a configuration in which the NMOS transistor 52 for deactivating the SPAD 39 is provided on the semiconductor substrate 21.

Furthermore, as illustrated in FIG. 23, the inverter 53 includes the PMOS transistor 54 and the NMOS transistor 55. As illustrated in FIG. 21, the pixel 12G-3 has a configuration in which the PMOS transistor 54 constituting the inverter 53 is provided on the semiconductor substrate 21, and the pixel 12G-4 has a configuration in which the NMOS transistor 55 constituting the inverter 53 is provided on the semiconductor substrate 21.

As described above, the sensor element 11G has a configuration in which the PMOS transistor 51, the NMOS transistor 52, the PMOS transistor 54, and the NMOS transistor 55 are arranged for each of the four pixels 12G-1 to 12G-4.

In the pixel 12G-1, an N-well 62-1, which is an n-type semiconductor region, is provided on the lower surface side of the semiconductor substrate 21 in order to provide the PMOS transistor 51. A side surface and an upper surface of the N-well 62-1 are surrounded by a P-well 35-1, and a separation portion 63-1 is provided at a boundary between the P-well 35-1 and the N-well 62-1. The separation portion 63-1 separates the P-well 35-1 and the N-well 62-1 from each other in the vicinity of the surface of the semiconductor substrate 21. Furthermore, similarly to the pixel 12 in FIG. 1, separation portions 45-1 and 46-1 are also provided.

In the pixel 12G-2, in order to provide the NMOS transistor 52, a P-well 35-2 which is a p-type semiconductor region is provided on the lower surface side of the semiconductor substrate 21, and an N-well 36-2 which is an n-type semiconductor region is provided so as to surround a side surface and an upper surface of the P-well 35-2. Furthermore, similarly to the pixel 12 in FIG. 1, separation portions 45-2 and 46-2 are also provided.

In the pixel 12G-3, an N-well 62-3, which is an n-type semiconductor region, is provided on the lower surface side of the semiconductor substrate 21 in order to provide the PMOS transistor 54. A side surface and an upper surface of the N-well 62-3 are surrounded by a P-well 35-3, and a separation portion 63-3 is provided at a boundary between the P-well 35-3 and the N-well 62-3. The separation portion 63-3 separates the P-well 35-3 and the N-well 62-3 from each other in the vicinity of the surface of the semiconductor substrate 21. Furthermore, similarly to the pixel 12 in FIG. 1, separation portions 45-3 and 46-3 are also provided.

In the pixel 12G-4, in order to provide the NMOS transistor 55, a P-well 35-4 which is a p-type semiconductor region is provided on the lower surface side of the semiconductor substrate 21, and an N-well 36-4 which is an n-type semiconductor region is provided so as to surround a side surface and an upper surface of the P-well 35-4. Furthermore, similarly to the pixel 12 in FIG. 1, separation portions 45-4 and 46-4 are also provided.

The sensor element 11G has a layout in which the metal wiring 47f connected to the VSS power supply is arranged between the metal wiring 47d that supplies the VDD power supply to a drain region 64-1 of the PMOS transistor 51 and a drain region 64-3 of the PMOS transistor 54 and the metal wiring 47e that supplies the VDD power supply to the N-wells 62-1 and 62-3. By arranging the metal wiring 47f in this manner, it is possible to shield between the adjacent metal wiring 47d and metal wiring 47e.

The sensor element 11G is configured as described above, and the PMOS transistor 51, the NMOS transistor 52, the PMOS transistor 54, and the NMOS transistor 55 are provided on the side of the sensor substrate 13 of the pixel 12G, so that it is possible to achieve further downsizing and high functionality similarly to the sensor element 11 described above.

FIG. 23 illustrates an example of a circuit diagram of the pixels 12G-1 to 12G-4.

The pixels 12G-1 to 12G-4 are configured by connecting SPADs 39-1 to 39-4, the PMOS transistor 51 for quenching or recharging, the NMOS transistor 52 for deactivating SPAD 39 for gating, and the PMOS transistor 54 and the NMOS transistor 55 constituting the inverter 53. As illustrated, the pixels 12G-1 to 12G-4 have a shared structure that shares the PMOS transistor 51, the NMOS transistor 52, and the inverter 53.

As described with reference to FIGS. 20 to 22, the PMOS transistor 51, the NMOS transistor 52, the PMOS transistor 54, and the NMOS transistor 55 are formed on the sensor substrate 13. Therefore, the sensor substrate 13 and the logic substrate 14 are connected via the Cu—Cu connection portions 48a to 48d.

The Cu—Cu connection portions 48a-1 to 48a-4 respectively connect the anodes of the SPADs 39-1 to 39-4 and a breakdown VRLD power supply. The Cu—Cu connection portion 48b connects the gate of the NMOS transistor 52 to the side of the logic substrate 14. The Cu—Cu connection portion 48c connects the output terminal of the inverter 53 to the side of the logic substrate 14. The Cu—Cu connection portion 48d connects the gate of the PMOS transistor 51 to the side of the logic substrate 14.

Note that the arrangement (allocation to the pixels 12G-1 to 12G-4) of the PMOS transistor 51, the NMOS transistor 52, the PMOS transistor 54, and the NMOS transistor 55, the layout of the metal wiring 47, and the like are not limited to the arrangement and layout illustrated in FIG. 22, and are only required to be any arrangement and layout that realize the wiring of the circuit diagram illustrated in FIG. 23.

By the way, in the present embodiment, the configuration in which a signal is output according to the cathode voltage of the SPAD 39 has been described, but the present technology may be applied to a configuration in which a signal is output according to the anode voltage of the SPAD 39 (positive voltage application). In this case, in the sensor element 11 of each configuration example described above, the anode region and the cathode region are inverted.

### <Configuration Example of Ranging System>

The sensor element 11 of each embodiment as described above can be applied to a ranging system that detects a distance to a subject in a depth direction for each pixel using the ToF method and captures a distance image that is an image including a distance pixel signal based on the detected distance.

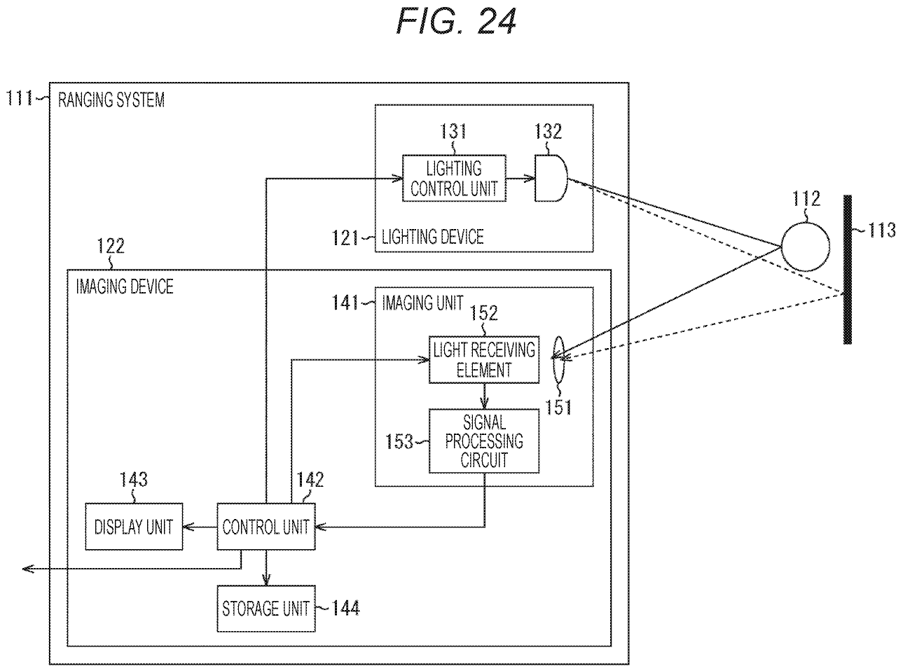

FIG. 24 is a block diagram illustrating a configuration example of an embodiment of a ranging system 111 to which the present technology is applied.

As illustrated in FIG. 24, the ranging system 111 includes a lighting device 121 and an imaging device 122.

The lighting device 121 includes a lighting control unit 131 and a light source 132.

The lighting control unit 131 controls a pattern in which the light source 132 emits light under the control of a control unit 142 of the imaging device 122. Specifically, the lighting control unit 131 controls the pattern in which the light source 132 emits light according to an irradiation code included in the irradiation signal supplied from the control unit 142. For example, the irradiation code has two values of 1 (High) and 0 (Low), and the lighting control unit 131 turns on the light source 132 when the value of the irradiation code is 1 and turns off the light source 132 when the value of the irradiation code is 0.

The light source 132 emits light in a predetermined wavelength region under the control of the lighting control unit 131. The light source 132 includes, for example, an infrared laser diode. Note that the type of the light source 132 and the wavelength range of the irradiation light can be arbitrarily set according to the application of the ranging system 111 and the like.

The imaging device 122 is a device that receives reflected light obtained by reflecting light (irradiation light) emitted from the lighting device 121 by the subject 112, the subject 113, and the like. The imaging device 122 includes an imaging unit 141, the control unit 142, a display unit 143, and a storage unit 144.

The imaging unit 141 includes a lens 151, a light receiving element 152, and a signal processing circuit 153.

The lens 151 forms an image of incident light on a light receiving surface of the light receiving element 152. Note that the configuration of the lens 151 is arbitrary, and for example, the lens 151 can be configured by a plurality of lens groups.

The sensor element 11 to which the present technology is applied is applied as the light receiving element 152. Under the control of the control unit 142, the light receiving element 152 receives reflected light from the subject 112, the subject 113, and the like, and supplies a pixel signal obtained as a result to the signal processing circuit 153. This pixel signal represents a digital count value obtained by counting a time from when the lighting device 121 emits the irradiation light to when the light receiving element 152 receives the irradiation light. A light emission timing signal indicating a timing at which the light source 132 emits light is also supplied from the control unit 142 to the light receiving element 152.

The signal processing circuit 153 processes the pixel signal supplied from the light receiving element 152 under the control of the control unit 142. For example, the signal processing circuit 153 detects a distance to the subject for each pixel based on the pixel signal supplied from the light receiving element 152, and generates a distance image indicating the distance to the subject for each pixel. Specifically, the signal processing circuit 153 acquires a time (count value) from when the light source 132 emits light to when each pixel of the light receiving element 152 receives the light a plurality of times (for example, several 1000 to several tens of thousands of times) for each pixel. The signal processing circuit 153 creates a histogram corresponding to the acquired time. Then, by detecting a peak of the histogram, the signal processing circuit 153 determines the time until the light emitted from the light source 132 is reflected by the subject 112 or the subject 113 and returns. Moreover, the signal processing circuit 153 performs an arithmetic operation to obtain the distance to the object based on the determined time and light speed. The signal processing circuit 153 supplies the generated distance image to the control unit 142.

The control unit 142 includes, for example, a control circuit such as a field programmable gate array (FPGA) or a digital signal processor (DSP), a processor, and the like. The control unit 142 controls the lighting control unit 131 and the light receiving element 152. Specifically, the control unit 142 supplies an irradiation signal to the lighting control unit 131 and supplies a light emission timing signal to the light receiving element 152. The light source 132 emits irradiation light according to the irradiation signal. The light emission timing signal may be an irradiation signal supplied to the lighting control unit 131. Furthermore, the control unit 142 supplies the distance image acquired from the imaging unit 141 to the display unit 143 and causes the display unit 143 to display the distance image. Moreover, the control unit 142 stores the distance image acquired from the imaging unit 141 in the storage unit 144. Furthermore, the control unit 142 outputs the distance image acquired from the imaging unit 141 to the outside.

The display unit 143 includes, for example, a panel type display device such as a liquid crystal display device or an organic electro luminescence (EL) display device.

The storage unit 144 can include an arbitrary storage device, a storage medium, or the like, and stores a distance image or the like.

In the ranging system 111 configured as described above, for example, downsizing and high functionality can be achieved by applying the sensor element 11 to which the present technology is applied.

### <Usage Example of Image Sensor>

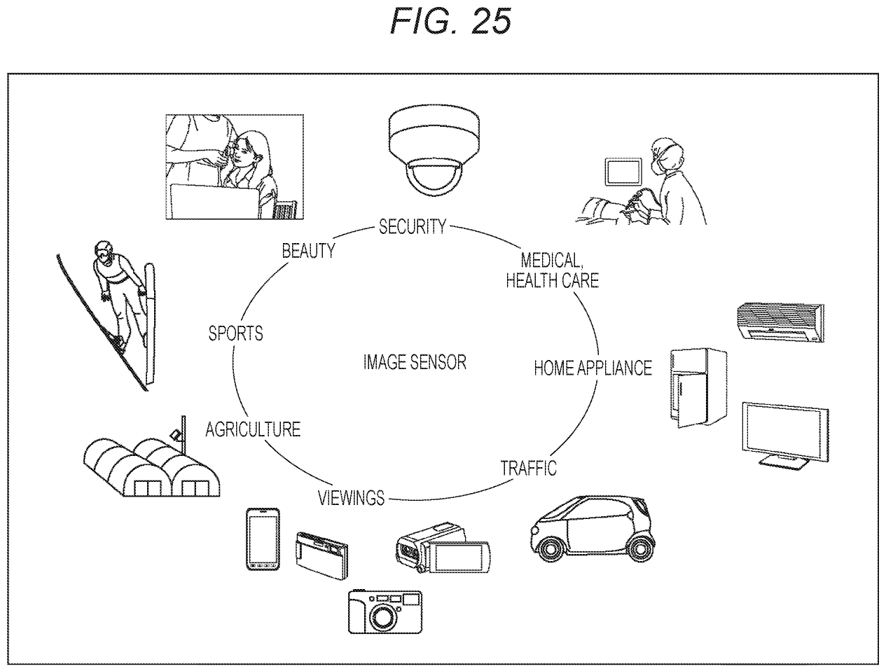

FIG. 25 is a diagram illustrating a usage example of using the above-described image sensor (sensor element 11).

The image sensor described above can be used in various cases for sensing light such as visible light, infrared light, ultraviolet light, and X-ray as described below, for example.
A device which takes an image to be used for viewing such as a digital camera and portable equipment with a camera function
A device for traffic purpose such as an in-vehicle sensor which takes images of the front, rear, surroundings, interior and the like of an automobile, a surveillance camera for monitoring traveling vehicles and roads, and a ranging sensor which measures a distance between vehicles and the like for safe driving such as automatic stop, recognition of a driver's condition and the like.
A device for home appliance such as a television, a refrigerator, and an air conditioner that takes an image of a user's gesture and performs a device operation according to the gesture
A device for medical and health care use such as an endoscope and a device that performs angiography by receiving infrared light
A device for security use such as a security monitoring camera and an individual authentication camera
A device for beauty care such as a skin measuring device that images skin and a microscope that images scalp
A device for sporting use such as an action camera and a wearable camera for sporting use and the like
A device for agricultural use such as a camera for monitoring land and crop states

### <Combination Examples of Configurations>

Note that the present technology can also have the following configuration.

(1)

A sensor element including:
a sensor substrate in which a single photon avalanche diode (SPAD) is provided on a semiconductor substrate for each pixel;
a logic substrate laminated on the sensor substrate and provided with a logic circuit; and
a plurality of transistors used to output a signal according to a cathode voltage or an anode voltage of the SPAD,
in which at least some of the plurality of the transistors are provided in a well formed in the semiconductor substrate of the sensor substrate.

(2)

The sensor element according to (1) described above, in which
the transistors provided on the sensor substrate are negative-channel metal-oxide semiconductor (NMOS) transistors,
a P-well is provided as the well on a front surface side of the semiconductor substrate, and
an N-well is provided so as to surround a side surface and an upper surface of the P-well, and an N-type multiplication region and a P-type multiplication region constituting the SPAD are arranged so as to be laminated on the N-well.

(3)

The sensor element according to (2) described above, further including:
a first separation portion that separates the P-well and the N-well in a vicinity of a surface of the semiconductor substrate; and
a second separation portion that separates one of a cathode region and an anode region provided in a vicinity of the surface of the semiconductor substrate of the N-well from another of the anode region and the cathode region provided in a vicinity of the surface of the semiconductor substrate along an outer periphery of the pixel.

(4)

The sensor element according to (1) described above, in which
the transistors provided on the sensor substrate is positive-channel metal-oxide semiconductor (PMOS) transistors,
a first N-well is provided as the well on a front surface side of the semiconductor substrate, and
a P-well is provided so as to surround a side surface and an upper surface of the first N-well, a second N-well is provided so as to surround a side surface and an upper surface of the P-well, and an N-type multiplication region and a P-type multiplication region constituting the SPAD are arranged so as to be laminated on the second N-well.

(5)

The sensor element according to (4) described above, further including:
a first separation portion that separates the P-well and the second N-well in a vicinity of a surface of the semiconductor substrate;
a second separation portion that separates one of a cathode region and an anode region provided in a vicinity of the surface of the semiconductor substrate of the second N-well from another of the anode region and the cathode region provided in a vicinity of the surface of the semiconductor substrate along an outer periphery of the pixel; and
a third separation portion that separates the P-well and the first N-well in a vicinity of the surface of the semiconductor substrate.

(6)

The sensor element according to (1) described above, in which
the transistors provided in the sensor substrate are an NMOS transistor that deactivates the SPAD and a PMOS transistor for quenching or recharging,
a first N-well in which the PMOS transistor is disposed is provided as the well on a front surface side of the semiconductor substrate, and a P-well in which the NMOS transistor is disposed is provided so as to surround a side surface and an upper surface of the first N-well, and
a second N-well is provided so as to surround a side surface and an upper surface of the P-well, and an N-type multiplication region and a P-type multiplication region constituting the SPAD are arranged so as to be laminated on the second N-well.

(7)

The sensor element according to (6) described above, further including:
a first separation portion that separates the P-well and the second N-well in a vicinity of a surface of the semiconductor substrate;
a second separation portion that separates one of a cathode region and an anode region provided in a vicinity of the surface of the semiconductor substrate of the second N-well from another of the anode region and the cathode region provided in a vicinity of the surface of the semiconductor substrate along an outer periphery of the pixel; and
a third separation portion that separates the P-well and the first N-well in a vicinity of the surface of the semiconductor substrate.

(8)

The sensor element according to (1) described above, in which
the transistors provided in the sensor substrate are a first NMOS transistor that deactivates the SPAD, a first PMOS transistor for quenching or recharging, and a second NMOS transistor and a second PMOS transistor constituting an inverter,
a first N-well in which the first PMOS transistor and the second PMOS transistor are disposed is provided as the well on a front surface side of the semiconductor substrate, and a P-well in which the first NMOS transistor and the second NMOS transistor are disposed is provided so as to surround a side surface and an upper surface of the first N-well, and
a second N-well is provided so as to surround a side surface and an upper surface of the P-well, and an N-type multiplication region and a P-type multiplication region constituting the SPAD are arranged so as to be laminated on the second N-well.

(9)

The sensor element according to (8) described above, further including:
a first separation portion that separates the P-well and the second N-well in a vicinity of a surface of the semiconductor substrate;
a second separation portion that separates one of a cathode region and an anode region provided in a vicinity of the surface of the semiconductor substrate of the second N-well from another of the anode region and the cathode region provided in a vicinity of the surface of the semiconductor substrate along an outer periphery of the pixel; and
a third separation portion that separates the P-well and the first N-well in a vicinity of the surface of the semiconductor substrate.

(10)

The sensor element according to (9) described above, in which
a shield wiring is disposed between a wiring that supplies a VDD power supply to drain regions of the first PMOS transistor and the second PMOS transistor and a wiring that supplies a VDD power supply to the first N-well.

(11)

The sensor element according to any one of (1) to (10) described above, in which
an anode region that applies an anode voltage to the pixel is disposed on a back surface side of the semiconductor substrate.

(12)

The sensor element according to (11) described above, in which
a hole accumulation region connected to the anode region and provided so as to surround a side surface of the pixel is formed in a range deeper than a predetermined depth from a front surface side of the semiconductor substrate.

(13)

The sensor element according to (12) described above, in which
an insulating film is provided in a range shallower than a predetermined depth from a front surface side of the semiconductor substrate so as to surround a side surface of the pixel.

(14)

The sensor element according to (1) described above, in which
the transistors provided in the sensor substrate are a first NMOS transistor that deactivates the SPAD, a first PMOS transistor for quenching or recharging, and a second NMOS transistor and a second PMOS transistor constituting an inverter, and
the first NMOS transistor, the first PMOS transistor, the second NMOS transistor, and the second PMOS transistor are individually disposed in four of the pixels.

(15)

A ranging system including:
a lighting device that emits irradiation light; and
a sensor element that detects reflected light with respect to the irradiation light,
in which the sensor element includes:
a sensor substrate in which a single photon avalanche diode (SPAD) is provided on a semiconductor substrate for each pixel;
a logic substrate laminated on the sensor substrate and provided with a logic circuit; and
a plurality of transistors used to output a signal according to a cathode voltage or an anode voltage of the SPAD, and
at least some of the plurality of the transistors are provided in a well formed in the semiconductor substrate of the sensor substrate.

Note that the present embodiment is not limited to the above-described embodiment, and various modifications can be made without departing from the gist of the present disclosure. Furthermore, the effects described in the present specification are merely examples and are not limited, and other effects may be provided.

### REFERENCE SIGNS LIST

11 Sensor element
12 Pixel
13 Sensor substrate
14 Logic substrate
31 Well layer
32 Pixel isolation portion
33 Hole accumulation region
34 Anode region
35 P-well
36 N-well
37 N-type multiplication region
38 P-type multiplication region
39 SPAD
40 NMOS transistor
44 Cathode region
45 and 46 Separation portion
47 Metal wiring
48 Cu—Cu connection portion
51 PMOS transistor
52 NMOS transistor
53 Inverter

1. A sensor element comprising:
a sensor substrate in which a single photon avalanche diode (SPAD) is provided on a semiconductor substrate for each pixel;
a logic substrate laminated on the sensor substrate and provided with a logic circuit; and
a plurality of transistors used to output a signal according to a cathode voltage or an anode voltage of the SPAD,
wherein at least some of the plurality of the transistors are provided in a well formed in the semiconductor substrate of the sensor substrate.

2. The sensor element according to claim 1, wherein
the transistors provided on the sensor substrate are negative-channel metal-oxide semiconductor (NMOS) transistors,
a P-well is provided as the well on a front surface side of the semiconductor substrate, and
an N-well is provided so as to surround a side surface and an upper surface of the P-well, and an N-type multiplication region and a P-type multiplication region constituting the SPAD are arranged so as to be laminated on the N-well.

3. The sensor element according to claim 2, further comprising:
a first separation portion that separates the P-well and the N-well in a vicinity of a surface of the semiconductor substrate; and
a second separation portion that separates one of a cathode region and an anode region provided in a vicinity of the surface of the semiconductor substrate of the N-well from another of the anode region and the cathode region provided in a vicinity of the surface of the semiconductor substrate along an outer periphery of the pixel.

4. The sensor element according to claim 1, wherein
the transistors provided on the sensor substrate are positive-channel metal-oxide semiconductor (PMOS) transistors,
a first N-well is provided as the well on a front surface side of the semiconductor substrate, and
a P-well is provided so as to surround a side surface and an upper surface of the first N-well, a second N-well is provided so as to surround a side surface and an upper surface of the P-well, and an N-type multiplication region and a P-type multiplication region constituting the SPAD are arranged so as to be laminated on the second N-well.

5. The sensor element according to claim 4, further comprising:
a first separation portion that separates the P-well and the second N-well in a vicinity of a surface of the semiconductor substrate;
a second separation portion that separates one of a cathode region and an anode region provided in a vicinity of the surface of the semiconductor substrate of the second N-well from another of the anode region and the cathode region provided in a vicinity of the surface of the semiconductor substrate along an outer periphery of the pixel; and
a third separation portion that separates the P-well and the first N-well in a vicinity of the surface of the semiconductor substrate.

6. The sensor element according to claim 1, wherein
the transistors provided in the sensor substrate are an NMOS transistor that deactivates the SPAD and a PMOS transistor for quenching or recharging,
a first N-well in which the PMOS transistor is disposed is provided as the well on a front surface side of the semiconductor substrate, and a P-well in which the NMOS transistor is disposed is provided so as to surround a side surface and an upper surface of the first N-well, and
a second N-well is provided so as to surround a side surface and an upper surface of the P-well, and an N-type multiplication region and a P-type multiplication region constituting the SPAD are arranged so as to be laminated on the second N-well.

7. The sensor element according to claim 6, further comprising:
a first separation portion that separates the P-well and the second N-well in a vicinity of a surface of the semiconductor substrate;
a second separation portion that separates one of a cathode region and an anode region provided in a vicinity of the surface of the semiconductor substrate of the second N-well from another of the anode region and the cathode region provided in a vicinity of the surface of the semiconductor substrate along an outer periphery of the pixel; and
a third separation portion that separates the P-well and the first N-well in a vicinity of the surface of the semiconductor substrate.

8. The sensor element according to claim 1, wherein
the transistors provided in the sensor substrate are a first NMOS transistor that deactivates the SPAD, a first PMOS transistor for quenching or recharging, and a second NMOS transistor and a second PMOS transistor constituting an inverter,
a first N-well in which the first PMOS transistor and the second PMOS transistor are disposed is provided as the well on a front surface side of the semiconductor substrate, and a P-well in which the first NMOS transistor and the second NMOS transistor are disposed is provided so as to surround a side surface and an upper surface of the first N-well, and
a second N-well is provided so as to surround a side surface and an upper surface of the P-well, and an N-type multiplication region and a P-type multiplication region constituting the SPAD are arranged so as to be laminated on the second N-well.

9. The sensor element according to claim 8, further comprising:
a first separation portion that separates the P-well and the second N-well in a vicinity of a surface of the semiconductor substrate;
a second separation portion that separates one of a cathode region and an anode region provided in a vicinity of the surface of the semiconductor substrate of the second N-well from another of the anode region and the cathode region provided in a vicinity of the surface of the semiconductor substrate along an outer periphery of the pixel; and
a third separation portion that separates the P-well and the first N-well in a vicinity of the surface of the semiconductor substrate.

10. The sensor element according to claim 9, wherein
a shield wiring is disposed between a wiring that supplies a VDD power supply to drain regions of the first PMOS transistor and the second PMOS transistor and a wiring that supplies a VDD power supply to the first N-well.

11. The sensor element according to claim 1, wherein
an anode region that applies an anode voltage to the pixel is disposed on a back surface side of the semiconductor substrate.

12. The sensor element according to claim 11, wherein
a hole accumulation region connected to the anode region and provided so as to surround a side surface of the pixel is formed in a range deeper than a predetermined depth from a front surface side of the semiconductor substrate.

13. The sensor element according to claim 12, wherein
an insulating film is provided in a range shallower than a predetermined depth from a front surface side of the semiconductor substrate so as to surround a side surface of the pixel.

14. The sensor element according to claim 1, wherein
the transistors provided in the sensor substrate are a first NMOS transistor that deactivates the SPAD, a first PMOS transistor for quenching or recharging, and a second NMOS transistor and a second PMOS transistor constituting an inverter, and
the first NMOS transistor, the first PMOS transistor, the second NMOS transistor, and the second PMOS transistor are individually disposed in four of the pixels.

15. A ranging system comprising:
a lighting device that emits irradiation light; and
a sensor element that detects reflected light with respect to the irradiation light,
wherein the sensor element includes:
a sensor substrate in which a single photon avalanche diode (SPAD) is provided on a semiconductor substrate for each pixel;
a logic substrate laminated on the sensor substrate and provided with a logic circuit; and
a plurality of transistors used to output a signal according to a cathode voltage or an anode voltage of the SPAD, and
at least some of the plurality of the transistors are provided in a well formed in the semiconductor substrate of the sensor substrate.
